(19) United States
(12) Patent Application Publication
(10) Pub. No.: US 2025/0290951 A1
(43) Pub. Date: Sep. 18, 2025

(54) STAGE, TEST APPARATUS, AND METHOD FOR OPERATING STAGE

(71) Applicant: Tokyo Electron Limited, Tokyo (JP)

(72) Inventors: Shigeru KASAI, Yamanashi (JP); Masahito KOBAYASHI, Yamanashi (JP); Hiroaki AGAWA, Yamanashi (JP)

(21) Appl. No.: 19/222,135

(22) Filed: May 29, 2025

Related U.S. Application Data
(63) Continuation of application No. PCT/JP2023/042490, filed on Nov. 28, 2023.

(30) Foreign Application Priority Data
Dec. 12, 2022 (JP) 2022-198076

(51) Int. Cl. G01R 1/04; G01R 31/26

(52) U.S. Cl. CPC G01R 1/04; G01R 31/2601

(57) ABSTRACT

A stage includes a base on which a substrate is to be mounted, and an elevation mechanism configured to raise and lower the base. The elevation mechanism includes a first adjustment mechanism configured to adjust an elevation position of the base by rotational drive of a drive motor, and includes a second adjustment mechanism configured to supply and discharge a pressure medium and adjust the elevation position of the base through the pressure medium.

### CROSS-REFERENCE TO RELATED APPLICATIONS

This application is a continuation of International Application No. PCT/JP2023/042490, filed on Nov. 28, 2023 and designating the U.S., which claims priority to Japanese Patent Application No. 2022-198076, filed on Dec. 12, 2022, the contents of which are incorporated herein by reference in their entirety.

### BACKGROUND

### 1. Technical Field

The present disclosure relates to a stage, a test apparatus, and a method for operating the stage.

### 2. Description of the Related Art

Patent Document 1 discloses a stage (test stage) that transfers a wafer to a predetermined position in a test apparatus for testing the wafer. The stage supports a base (mounting base) on which the wafer is mounted, by three elevation drive mechanisms. The stage also raises and lowers the base while monitoring elevation positions of the three elevation drive mechanisms.

The test apparatus brings numerous probes (for example, tens of thousands) into contact with the wafer during wafer test. For this reason, when raising the stage to bring the wafer into contact with each probe, a large load is applied to the stage from the probes.

### RELATED-ART DOCUMENT

Patent Document 1: Japanese Unexamined Patent Application Publication No. 2000-260852

### SUMMARY

A stage according to one aspect of the present disclosure includes a base on which a substrate is to be mounted, and an elevation mechanism configured to raise and lower the base. The elevation mechanism includes at least one first adjustment mechanism configured to adjust an elevation position of the base by rotational drive of a drive motor, and includes a second adjustment mechanism configured to supply and discharge a pressure medium, and to adjust the elevation position of the base through the pressure medium.

### BRIEF DESCRIPTION OF THE DRAWINGS

FIG. 1 is a schematic cross-sectional view showing a test apparatus including a stage according to one embodiment.

FIG. 2A is a schematic side view showing the stage provided in a test unit.

FIG. 2B is a plan view showing a mounting surface of the stage.

FIG. 3 is a schematic side sectional view showing a Z-axis movement mechanism for the stage.

FIG. 4A is a flowchart showing a method for operating the stage when raising the wafer.

FIG. 4B is a graph showing torque applied to a base when raising the wafer.

FIG. 5 is a block diagram showing a control flow of the Z-axis movement mechanism in a position control step.

FIG. 6 is a block diagram showing the control flow of the Z-axis movement mechanism in a torque control step.

FIG. 7 is a block diagram showing a control algorithm of each motor mechanism.

FIG. 8 is a flowchart showing an example of a method for operating the stage.

FIG. 9 is a schematic side sectional view showing the Z-axis movement mechanism in a modification.

### DETAILED DESCRIPTION

Various embodiments of the present disclosure will be described below with reference to the drawings. In each of the drawings, the same components are denoted by the same reference numerals, and duplicate description may be omitted.

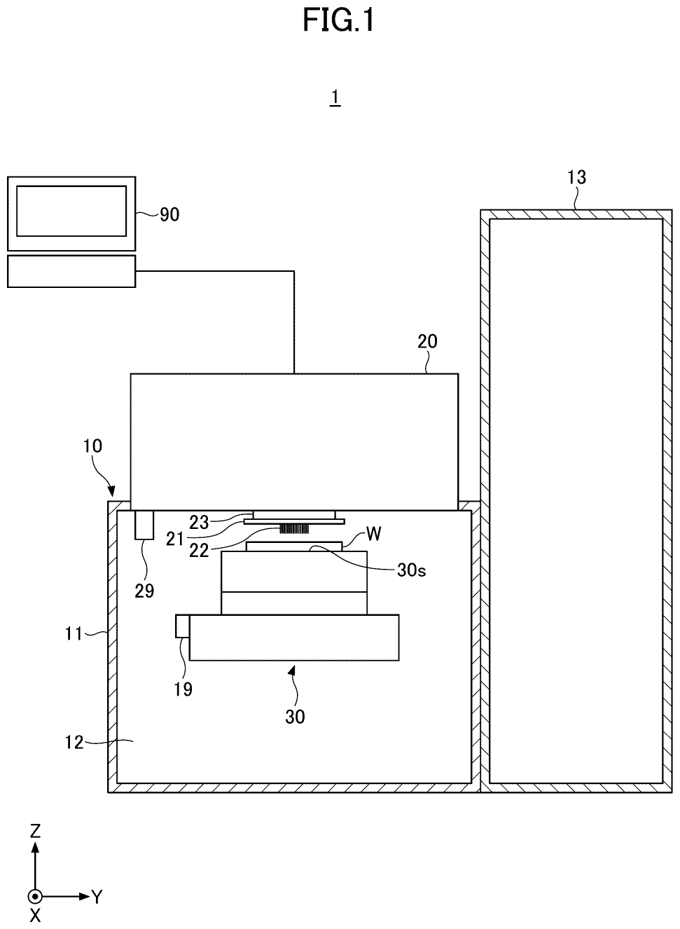

FIG. 1 is a schematic cross-sectional view showing a test apparatus 1 including a stage 30 according to one embodiment. As shown in FIG. 1, the test apparatus 1 according to the embodiment tests electrical characteristics of a wafer W, which is an example of a substrate. A semiconductor device, which is a device under test (DUT), is formed on the surface of the wafer W. The substrate is not limited to the wafer W, and may include a carrier, a glass substrate, a single chip, an electronic circuit board, or the like on which the DUT is placed. The DUT is not limited to the semiconductor device, and may be other electronic devices or the like.

The test apparatus 1 includes a test unit 10 that actually performs the test, a loader 13 disposed at a position adjacent to the test unit 10, and a tester 20 disposed on the test unit 10. Further, the test apparatus 1 includes a controller 90 that controls the operation of the test unit 10, the loader 13, and the tester 20.

The test unit 10 includes a rectangular parallelepiped housing 11, and has a test chamber 12 in the housing 11. The test chamber 12 houses the stage 30 on which the wafer W is mounted, and that transfers the wafer W to a desired three-dimensional coordinate position.

A front opening unified pod (FOUP), not shown, for holding wafers W is set in the loader 13. The loader 13 includes a transfer device (not shown). A given wafer W is taken out from the FOUP by the transfer device, and is transferred to the stage 30 in the test chamber 12. The loader 13 takes out a tested wafer W from the stage 30 by the transfer device, and accommodates the wafer W in the FOUP.

The test unit 10 includes a probe card 21 that is connected to the tester 20 via an interface 23 and is in an upper space of the test chamber 12. The probe card 21 has probes 22 at positions that face the wafer W. When moving the wafer W by the stage 30, each probe 22 contacts an electrode pad, a solder bump, or the like of each DUT for the wafer W. In this arrangement, the tester 20 outputs power and various signals to DUTs via the probe card 21 and the interface 23, and then receives signals transmitted from the DUTs via the probe card 21 and the interface 23.

The tester 20 has an internal motherboard (not shown) connected to the interface 23. The motherboard has slots into which test boards (not shown) are inserted, and is connected to the controller 90. The motherboard determines whether each DUT passes or fails based on the signal transmitted from the DUT for the wafer W. The tester 20 can perform different types of tests by appropriately replacing the test board.

Further, the test apparatus 1 may include a test-side camera 29 that captures the wafer W on the stage 30 at an appropriate position in the test chamber 12. The test-side camera 29 captures, for example, the inclination of the stage 30 and/or a position or the like of the wafer W that is mounted on the stage 30. Alternatively, the test apparatus 1 may include either the probe card 21 or a stage-side camera 19 that captures a contact state or the like between each probe 22 and the wafer W.

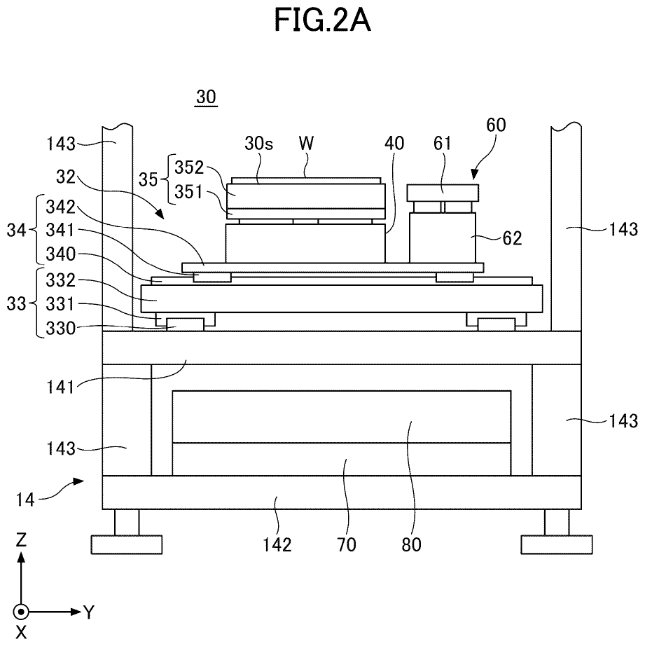

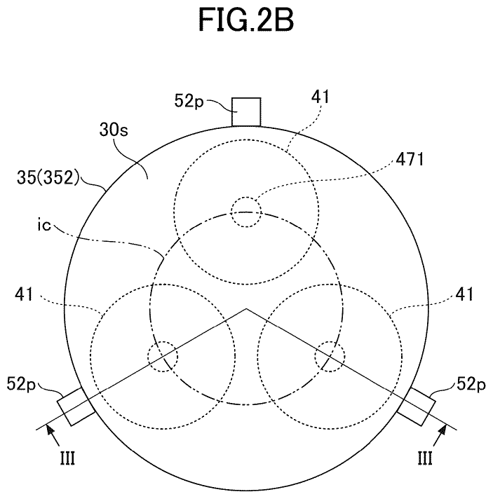

FIG. 2A is a schematic side view showing the stage 30 provided in the test unit 10. FIG. 2B is a plan view showing a mounting surface 30s of the stage 30. As shown in FIG. 2A, the stage 30 is provided on a frame structure 14 supporting a panel (not shown) that constitutes the exterior of the housing 11. The mounting surface 30s that is flat and supports the wafer W is formed on the upper surface of the stage 30.

The stage 30 transfers the wafer W mounted on the mounting surface 30s to an appropriate three-dimensional position (in an X-axis direction, a Y-axis direction, and a Z-axis direction) of the test chamber 12. For example, the stage 30 moves in a horizontal direction (X-axis and Y-axis directions) between a position near (or inside) the loader 13 and a position facing the probe card 21, to thereby adjust a horizontal position of the wafer W. The stage 30 also moves vertically (in the Z-axis direction) at a facing position between the probe card 21 and the wafer W, to thereby adjust an elevation position of the wafer W.

The stage 30 has a movement unit 32 (an X-axis movement mechanism 33, a Y-axis movement mechanism 34, and a Z-axis movement mechanism 40), a base 35, a probe polishing mechanism 60, a stage controller 70, and a motor drive unit 80. In the present embodiment, the frame structure 14 has a two-stage structure that includes an upper base 141 supporting the movement unit 32; a lower base 142 supporting both the stage controller 70 and the motor drive unit 80; and supports 143 provided at four corners of both the upper base 141 and the lower base 142.

The X-axis movement mechanism 33 of the movement unit 32 includes guide rails 330 that are fixed to the upper surface of the upper base 141 and extend along the X-axis direction; X-axis movable bodies 331 that are arranged on the respective guide rails 330; and an X-axis stage 332 supported by the X-axis movable bodies 331. The X-axis stage 332 has an X-axis drive unit (a motor, a gear mechanism, and the like), not shown, connected to the motor drive unit 80. The X-axis drive unit reciprocates the X-axis movable bodies 331 and the X-axis stage 332 in the X-axis direction, based on power supply from the motor drive unit 80, to thereby adjust an X-coordinate of the wafer W.

The Y-axis movement mechanism 34 includes guide rails 340 that are fixed to the upper surface of the X-axis stage 332 and extend along the Y-axis direction; Y-axis movable bodies 341 that are arranged on the respective guide rails 340; and a Y-axis stage 342 supported by the Y-axis movable bodies 341. The Y-axis stage 342 has a Y-axis drive unit (a motor, a gear mechanism, and the like), not shown, connected to the motor drive unit 80. The Y-axis drive unit reciprocates the Y-axis movable bodies 341 and the Y-axis stage 342 in the axial direction, based on power supply from the motor drive unit 80, to thereby adjust a Y-coordinate of the wafer W.

The Z-axis movement mechanism 40 is provided on the Y-axis stage 342, and holds the base 35 above the Y-axis stage 342. By displacing the base 35 in the Z-axis direction (vertical direction), the Z-axis movement mechanism 40 constitutes an elevation mechanism of the present embodiment for raising and lowering the wafer W that is mounted on the mounting surface 30s of the base 35. A configuration of the Z-axis movement mechanism 40 will be described in detail later.

The base 35 that is transferred by the movement unit 32 includes a bottom plate 351 supported by the Z-axis movement mechanism 40, and includes a chuck top 352 that is laminated on the upper side of the bottom plate 351 and that has the mounting surface 30s. The bottom plate 351 is supported by three drive units 41 of the Z-axis movement mechanism 40 described later. The chuck top 352 has a circular shape that is larger in diameter than the wafer W in plan view (see FIG. 2B), and the chuck top 352 is formed to have a thickness that is greater than that of the bottom plate 351. Although not shown, the chuck top 352 may include an appropriate holding unit (such as vacuum adsorption or a mechanical chuck) that holds the wafer W; a temperature control mechanism that adjusts the temperature of the mounting surface 30s; a temperature sensor that detects the temperature of the mounting surface 30s; and other components.

The probe polishing mechanism 60 of the stage 30 is provided at a position of the Y-axis stage 342 adjacent to the Z-axis movement mechanism 40. A polishing body 61 for polishing the probes 22 that protrude downward from the probe card 21 is provided at an upper portion of the probe polishing mechanism 60. The probe polishing mechanism 60 has a polishing-side Z-axis movement mechanism 62 that displaces the polishing body 61 in the Z-axis direction. The polishing-side Z-axis movement mechanism 62 is configured substantially similarly to the Z-axis movement mechanism 40.

The stage controller 70 is connected to the controller 90 of the test apparatus 1, and controls the operation of the stage 30 based on a command from the controller 90. The stage controller 70 has, for example, a main controller that controls the operation of the entire stage 30; a programmable logic controller (PLC) that controls the operation of the movement unit 32; a temperature controller that controls the temperature control mechanism; an illumination controller; a power supply unit; and other components (all not shown). The main controller of the stage controller 70 may be implemented by a computer built-in board having one or more processors, a memory, an input/output interface, an electronic circuit, and other components, which are not shown. The one or more processors are a combination of one or more selected from CPUs, GPUs, ASICs, FPGAs, circuits comprised of discrete semiconductors, and other components. The one or more processors execute and process one or more programs that are stored in a memory. The memory may include a non-volatile memory and a volatile memory.

The stage controller 70 controls the motor drive unit 80 based on a command from the controller 90, and after the wafer W is moved from the loader 13 to the base 35, the stage controller 70 operates the movement unit 32 to thereby move the wafer W in the horizontal direction. Then, at a position where the wafer W faces the probe card 21, the stage controller 70 raises the base 35 by the Z-axis movement mechanism 40 of the movement unit 32, so that the wafer W is in contact with one or more probes 22 of the probe card 21. In this state, the controller 90 starts an electrical test through the tester 20. After the test through the tester 20 is completed, the stage controller 70 lowers and horizontally moves the tested wafer W by performing a reverse operation of the movement operation described above. As a result, the stage controller 70 returns the wafer W to the loader 13.

As shown in FIG. 2B, the Z-axis movement mechanism 40 has the three drive units 41 that independently raise and lower the base 35, and each drive unit 41 supports the base 35. Shafts of the drive units 41 are located on a virtual circle ic that is separated by a predetermined radius from the center of the base 35, and these shafts are arranged at equal intervals along a circumferential direction of the virtual circle ic (every 120° around the center of the base 35). By individually raising and lowering each of the drive units 41 as arranged above, the Z-axis movement mechanism 40 can adjust the tilt of the base 35.

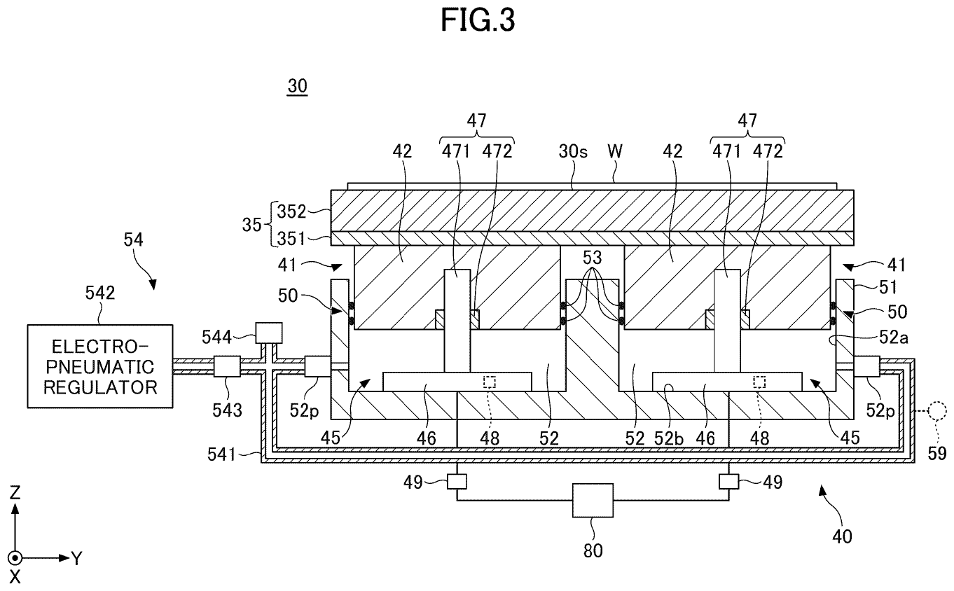

FIG. 3 is a schematic side sectional view showing the Z-axis movement mechanism 40 of the stage 30. As shown in FIG. 3, each of the three drive units 41 has a Z-axis movable body 42 that directly supports the bottom plate 351 of the base 35 and that can displace in the vertical direction. Each of the drive units 41 according to the present embodiment has two mechanisms that raise and lower the Z-axis movable body 42, namely, a motor mechanism 45 and a cylinder mechanism 50.

The motor mechanism 45 has a drive motor 46 that drives rotation based on the power supply from the motor drive unit 80. The type of the drive motor 46 is not particularly limited, but it is preferable to use a direct drive motor in order to make the Z-axis movement mechanism 40 compact. The direct drive motor is configured to be low with respect to the axial direction of the shaft portion 470, without using a reduction gear, and the direct drive motor can rotate at low velocity and high torque.

The motor mechanism 45 also has a power conversion unit 47 that converts the rotational drive of the drive motor 46 into linear drive, between the drive motor 46 and the Z-axis movable body 42. For example, the power conversion unit 47 may have a ball screw structure having both a ball screw 471 connected to a rotor (not shown) of the drive motor 46 (direct drive motor) and a nut 472 screwed to the ball screw 471. In this case, the ball screw 471 constitutes a shaft of each drive unit 41. With use of such a power conversion unit 47, the motor mechanism 45 rotates the ball screw 471 according to the rotation of the drive motor 46, and thus raises and lowers the Z-axis movable body 42 along the Z-axis direction.

Further, the motor mechanism 45 may include an encoder 48 that detects a rotation angle of the motor; a torque sensor 49 that detects, as torque (current value), a load applied to the drive motor 46 from the base 35; and other components. Here, if a speed reducer is connected to the drive motor 46, the torque of the drive motor 46 needs to be determined with consideration of the torque of the speed reducer. However, in the present embodiment, since the direct drive motor is applied to the drive motor 46, loss in torque transmission of the speed reducer no longer needs to be taken into consideration. Thus, the stage 30 can accurately detect the torque that is applied to the drive motor 46, through the torque sensor 49.

On the other hand, the cylinder mechanism 50 has a cylindrical recess 52 in a disk-shaped housing 51 of the Z-axis movement mechanism 40 that houses the motor mechanism 45, and the cylinder mechanism 50 causes the Z-axis movable body 42 itself, which is housed in the recess 52, to function as a piston. The cylinder mechanism 50 supplies and discharges air, which is a pressure medium, to the recess 52, thereby applying appropriate pressure (a floating force) to the lower surface of the Z-axis movable body 42. In this arrangement, the Z-axis movement mechanism 40 assists the raising and lowering of each Z-axis movable body 42, and thus the torque of each motor mechanism 45 can be reduced.

Specifically, in the disk-shaped housing 51, the recesses 52 are surrounded by: an inner peripheral surface 52a extending parallel to the vertical direction; and a bottom surface 52b parallel to the horizontal direction. These recesses 52 are opened at an upper portion of the disk-shaped housing 51. The above drive motor 46 is disposed on the bottom surface 52b. On the other hand, each Z-axis movable body 42 has one or more seal members 53 in contact with the inner peripheral surface 52a of the recess 52, on the outer peripheral surface (side peripheral surface) of the movable body. Each seal member 53 is made of an elastic material such as elastomer, and one or more given seal members 53 allow a given Z-axis movable body 42 to slide in the vertical direction while hermetically closing the recess 52 between the outer peripheral surface and the inner peripheral surface 52a of the Z-axis movable body 42.

In the cylinder mechanisms 50, a supply/discharge mechanism 54 is disposed outside the disk-shaped housing 51, and provides air to the recesses 52 that are closed by the Z-axis movable bodies 42. The supply/discharge mechanism 54 has a supply/discharge path 541 connected to ports 52p in communication with the recesses 52 of the disk-shaped housing 51. Further, the supply/discharge mechanism 54 has an electro-pneumatic regulator 542 connected to one end of the supply/discharge path 541, and has an open-close valve 543 and a relief valve 544 in the supply/discharge path 541 that is situated between a given recess 52 and the electro-pneumatic regulator 542.

The supply/discharge path 541 is configured by connecting pipes with internal air flow paths. The supply/discharge path 541 branches at a branch position in the middle of the supply/discharge path, depending upon the recesses 52 of the drive units 41. One end of each branch path of the supply/discharge path 541 is connected to a corresponding port 52p of the disk-shaped housing 51.

A primary side of the electro-pneumatic regulator 542 is connected to an air source such as a compressor (not shown), and the supply/discharge path 541 is connected to a secondary side of the electro-pneumatic regulator 542. The electro-pneumatic regulator 542 is connected to the stage controller 70, and supplies air adjusted to appropriate pneumatic pressure, to the supply/discharge path 541, under the control of the stage controller 70.

The open-close valve 543 is disposed on an upstream side of the supply/discharge path 541 in an air supply direction from the branch position. The open-close valve 543 is connected to the stage controller 70, and opens and closes a flow path of the supply/discharge path 541 under the control of the stage controller 70.

The relief valve 544 is disposed on a downstream side (for example, the branch position of the supply/discharge path 541) of the open-close valve 543. The relief valve 544 is connected to the stage controller 70, and switches between atmospheric release and isolation of a flow path of the supply/discharge path 541, under the control of the stage controller 70.

The stage controller 70 (see FIG. 2A) moves the stage 30 to a position facing the probe card 21. Then, by cooperating the motor mechanisms 45 and the cylinder mechanisms 50 of the drive units 41, the stage controller 70 raises and lowers the wafer W on the base 35 through the drive units 41. For example, when raising the wafer W, the stage controller 70 controls the position of the base 35 in the Z-axis direction by the motor mechanism 45, while canceling or compensating for the self-weight of the base 35 based on the pneumatic pressure from the cylinder mechanism 50. The control of the Z-axis movement mechanism 40 by the stage controller 70 will be described in detail below.

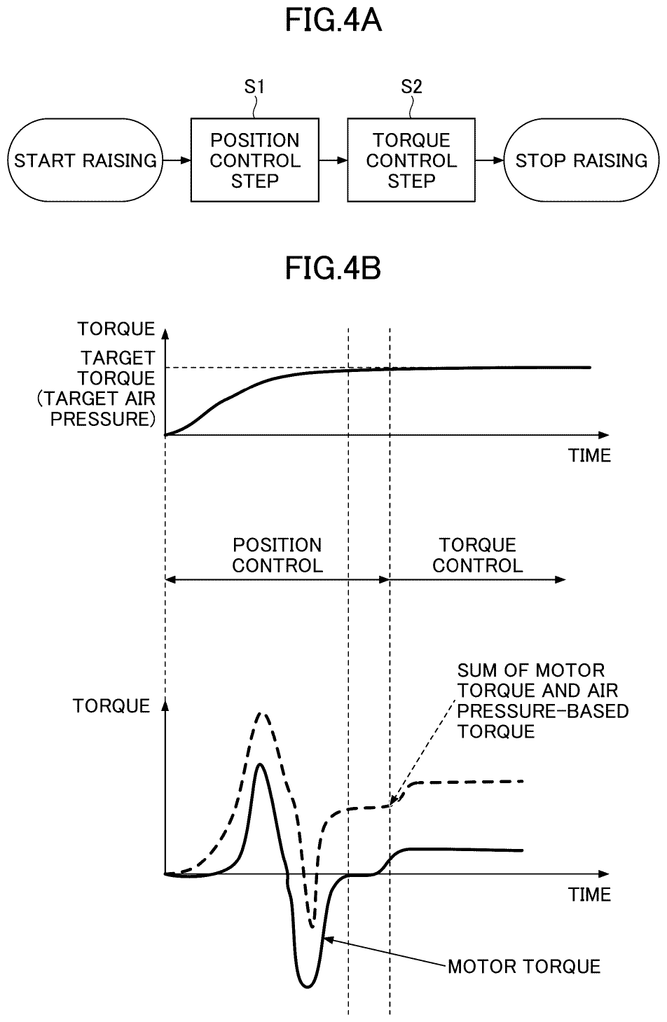

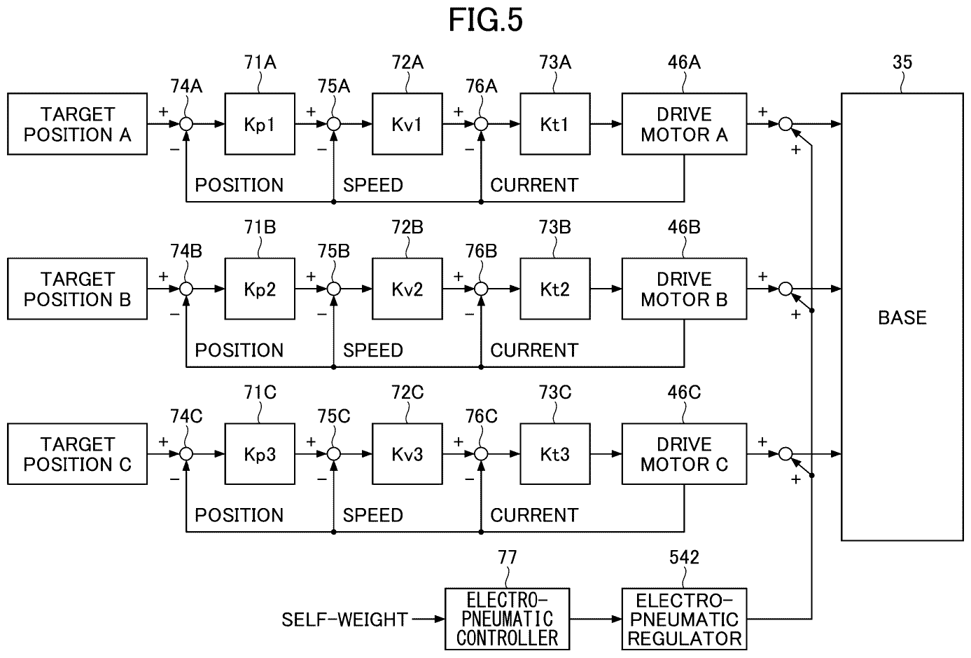

FIG. 4A is a flow diagram showing the method for operating the stage 30 when raising the wafer W. FIG. 4B is a graph showing the torque applied to the base 35 when raising the wafer W. As shown in FIG. 4A, the stage controller 70 sequentially performs a position control step (S1) and a torque control step (S2), when raising the wafer W mounted on the base 35. The position control step (S1) is a control performed during a period until each probe 22 of the probe card 21 contacts the wafer W. After each probe 22 contacts the wafer W, the torque control step (S2) is a control performed both during overdrive when the base 35 is slightly raised, and during testing of the wafer W.

That is, in the position control step (S1), the stage controller 70 adjusts an elevation position (or a 3D position including X-axis and Y-axis directions) of the wafer W, and causes the DUTs for the wafer W to contact the respective probes 22. When performing the position control step (S1), the stage controller 70 drives the electro-pneumatic regulator 542 to supply air to each recess 52, and adjusts pneumatic pressure in each recess 52 to target pressure. The target pressure in each recess 52 is pressure that can compensate for the self-weight of the base 35, and is obtained by holding a weight value of the base 35 in advance and by calculating required pneumatic pressure based on the weight value. In this arrangement, the motor mechanism 45 greatly reduces (or becomes zero) the torque that allows for raising of the base 35 itself. The self-weight of the base 35 may include the weight of the Z-axis movable bodies 42 and/or the weight of the wafer W.

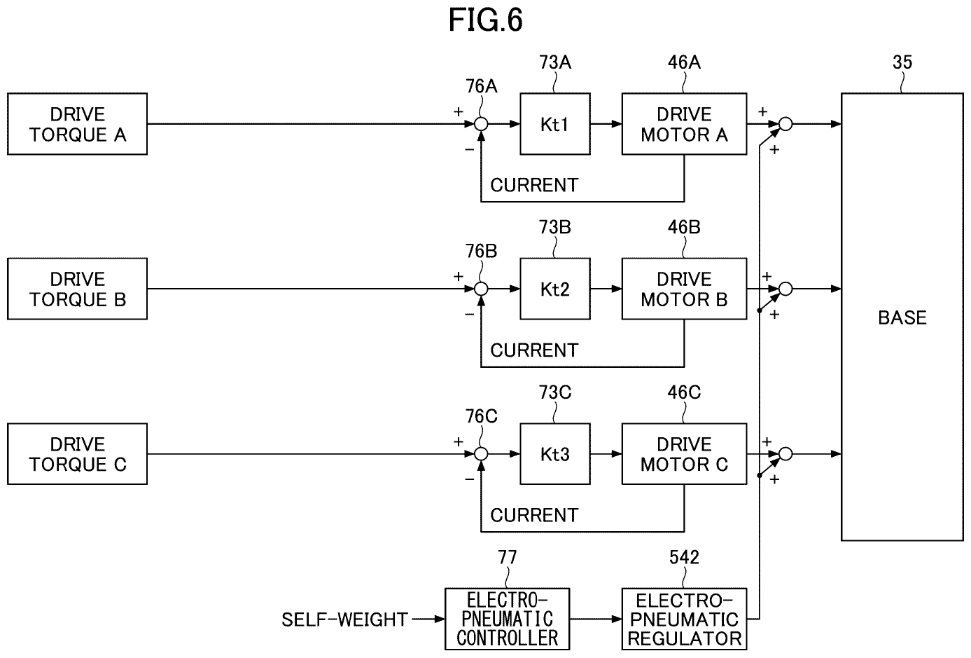

FIG. 5 is a block diagram showing the control flow of each Z-axis movement mechanism 40 in the position control step. In FIG. 5 and FIG. 6 described below, the three drive motors 46 are labeled with the symbols A, B, and C for ease of understanding. In the position control step (S1), the Z-axis movement mechanism 40 detects a position (rotation angle), velocity, and current (acceleration) of each drive motor 46 as shown in FIG. 5, and transmits, as state information, information of the position, velocity, and current to the stage controller 70 or the motor drive unit 80. The position, velocity, and acceleration of each drive motor 46 can be obtained from the encoder 48 that is provided in a corresponding drive unit 41. Alternatively, the current of each drive motor 46 may be directly detected by a corresponding torque sensor 49. In the following, for convenience of explanation, the state information that is detected in each drive motor 46 may be referred to as an actual position, an actual velocity, and an actual current (actual acceleration).

As functional units that drive the drive motors 46A, 46B, and 46C of the respective drive units 41, the stage controller 70 (or the motor drive unit 80) includes first calculation units 71A, 71B, and 71C, second calculation units 72A, 72B, and 72C, and third calculation units 73A, 73B, and 73C. The stage controller 70 further has first differential units 74A, 74B, and 74C upstream of the respective first calculation units 71A, 71B, and 71C; second differential units 75A, 75B, and 75C upstream of the respective second calculation units 72A, 72B, and 72C; and third differential units 76A, 76B, and 76C upstream of the third calculation units 73A, 73B, and 73C. The first calculation units 71A to 71C, the second calculation units 72A to 72C, the third calculation units 73A to 73C, the first differential units 74A to 74C, the second differential units 75A to 75C, and the third differential units 76A to 76C are software functional units according to the present embodiment. However, these units are not limited to the software functional units, and may be hardware functional units that use discrete semiconductors.

Target positions A, B, and C of the drive motors 46A, 46B, and 46C, and actual positions of the drive motors 46A, 46B, and 46C are input to the first differential units 74A, 74B, and 74C, respectively. In this arrangement, the first differential units 74A, 74B, and 74C calculate differences between the target positions A, B, and C and the actual positions, respectively. Similarly, target velocities and actual velocities of the drive motors 46A, 46B, and 46C are input to the second differential units 75A, 75B, and 75C, respectively. In this arrangement, the second differential units 75A, 75B, and 75C calculate the differences between the target velocities and the actual velocities, respectively. Target currents and actual currents of the drive motors 46A, 46B, and 46C are input to the third differential units 76A, 76B, and 76C, respectively. In this arrangement, the third differential units 76A, 76B, and 76C calculate the differences between the target currents and the actual currents, respectively. The actual currents of the drive motors 46A, 46B, and 46C are proportional to the torque (=acceleration) applied to the drive motors 46A, 46B, and 46C, respectively. In this arrangement, the third differential units 76A, 76B, and 76C may be each configured to calculate the difference between the target acceleration and the actual acceleration, by converting the target current into the target acceleration.

The first calculation units 71A, 71B, and 71C respectively calculate correction positions that are used to adjust the positions based on position differences that are input from the first differential units 74A, 74B, and 74C. Further, the first calculation units 71A, 71B, and 71C respectively calculate the target velocities corresponding to the correction positions. The second calculation units 72A, 72B, and 72C respectively calculate correction velocities that are used to adjust velocities of the drive motors 46A, 46B, and 46C based on velocity differences that are input from the second differential units 75A, 75B, and 75C. Further, the second calculation units 72A, 72B, and 72C respectively calculate target currents corresponding to the correction velocities. The third calculation units 73A, 73B, and 73C respectively calculate amounts of power supplied to the drive motors 46 based on current differences that are input from the third differential units 76A, 76B, and 76C. The rotation drive of the drive motor 46A, 46B, and 46C is controlled according to the respective amounts of power supplied from the stage controller 70.

In order to control the electro-pneumatic regulator 542 for the cylinder mechanisms 50, the stage controller 70 has an interior electro-pneumatic controller 77. The electro-pneumatic controller 77 retrieves the self-weight (a weight value) of the base 35 from the memory, then calculates target torque (i.e., target pneumatic pressure) applied to the base 35 according to the self-weight of the base 35, and controls the electro-pneumatic regulator 542 according to the target pneumatic pressure. Based on a command from the electro-pneumatic controller 77, the electro-pneumatic regulator 542 uniformly supplies the pneumatic pressure to the recesses 52 for the three drive units 41, to thereby apply pneumatic pressure enabling the self-weight of the base 35 to be canceled, to each Z-axis movable body 42.

In this arrangement, in the position control step (S1), by current control that does not use the self-weight of the base 35, the drive motors 46A, 46B, and 46C of the drive units 41 can adjust a relative elevation position of the wafer W and the base 35, with respect to each probe 22.

FIG. 6 is a block diagram showing the control flow of each Z-axis movement mechanism 40 in the torque control step. As shown in FIG. 6, in the torque control step (S2), the Z-axis movement mechanism 40 detects the current (torque) of each drive motor 46, and transmits a detection signal of the actual current as state information, to the stage controller 70 or the motor drive unit 80.

The stage controller 70 (or the motor drive unit 80) includes the third calculation units 73A, 73B, and 73C and the third differential units 76A, 76B, and 76C, as functional units that drive the drive motors 46A, 46B, and 46C of the drive units 41. In other words, in the torque control step (S2), the first calculation units 71A, 71B, and 71C, the second calculation units 72A, 72B, and 72C, the first differential units 74A, 74B, and 74C, and the second differential units 75A, 75B, and 75C are omitted.

Target drive torques A, B, and C of the drive motors 46A, 46B, and 46C are respectively input to the third differential units 76A, 76B, and 76C from the stage controller 70. For example, the target drive torques A, B, and C are calculated based on loads received from the probes 22, in an overdrive operation in which each DUT for the wafer W is raised so as to ensure the contact with the probe 22. The third differential units 76A, 76B, and 76C calculate differences between the target currents (target torques) that are obtained based on the target drive torques A, B, and C, and the actual currents (actual torques) of the drive motors 46A, 46B, and 46C.

The third calculation units 73A, 73B, and 73C receive the current differences that are calculated in the third differential units 76A, 76B, and 76C. The third calculation units 73A, 73B, and 73C respectively calculate amounts of power supplied to the drive motors 46A, 46B, and 46C based on the received current differences (such that the current differences become zero). The rotational drive of the drive motors 46A to 46C is controlled according to the respective amounts of power supplied from the stage controller 70.

In the torque control step (S2), the stage controller 70 also includes an interior electro-pneumatic controller 77, as described in the position control step (S1). The electro-pneumatic controller 77 calculates pneumatic pressure that is applied to the base 35, according to the self-weight of the base 35 that is stored in the memory. Then, the electro-pneumatic controller 77 controls the electro-pneumatic regulator 542 according to the pneumatic pressure.

In this arrangement, in the torque control step (S2), by only the current control that does not use a position and velocity, the drive motors 46A, 46B, and 46C of the drive units 41 can adjust positions of the wafer W and the base 35, with respect to each probe 22 in contact with the wafer W. That is, pneumatic pressures in the cylinder mechanisms 50 cancel the self-weight of the base 35, such that the drive motors 46A, 46B, and 46C apply torque only in response to the loads received from the probes 22 in contact with the wafer W. As a result, the stage 30 can perform the overdrive operation with reduced torque.

Referring back to FIGS. 4A and 4B, by switching from the position control step (S1) to the torque control step (S2) during the raising of the wafer W, the stage controller 70 appropriately controls the position of the stage 30 in the Z-axis direction. As shown in the lower part of FIG. 4B, a torque obtained based on the pneumatic pressure in the cylinder mechanism 50 is added to the torque of each motor mechanism 45, thereby increasing the overall torque that is applied to the base 35 (see the dashed line of FIG. 4B).

Here, as shown in the upper part of FIG. 4B, the torque due to the pneumatic pressure in each cylinder mechanism 50 gradually increases from the start of the position control step (S1). On the other hand, the torque of each motor mechanism 45 that is obtained based on the power supply quickly changes according to a power supply amount. For example, in the position control step (S1), the torque of each motor mechanism 45 rapidly increases after the start of the position control step, then decreases, and increases again. Then, in the torque control step (S2), when applying the load from each probe 22 to the wafer W and the base 35, a substantially constant torque of each motor mechanism 45 is applied so as to correspond to the load of each probe 22.

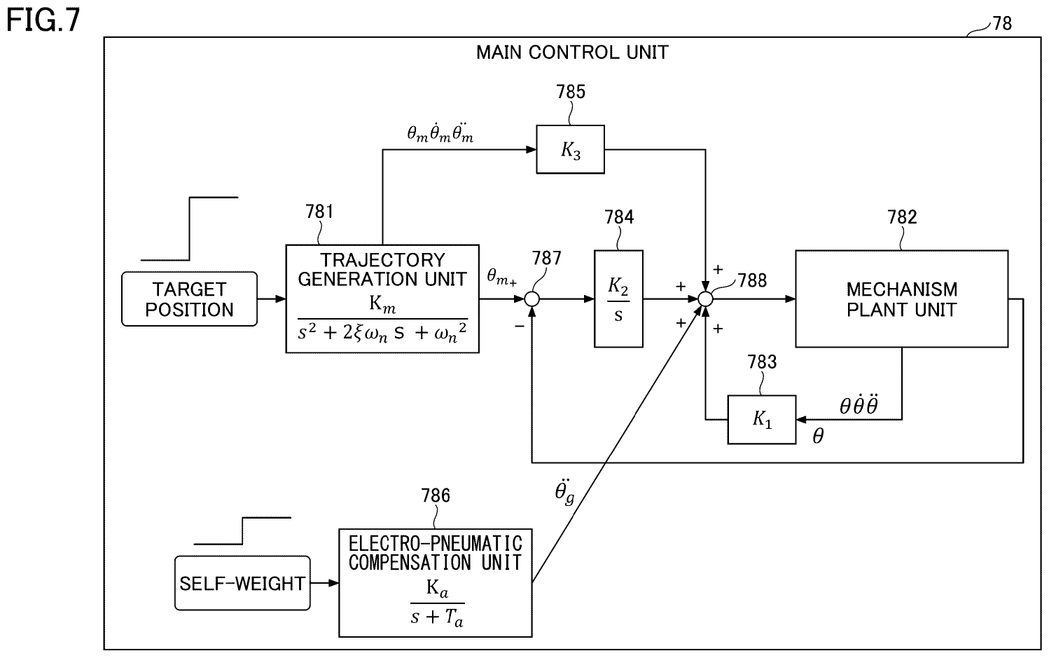

In other words, in the position control step (S1), a delay time occurs in the torque due to the pneumatic pressure of each cylinder mechanism 50, with respect to the target current (target torque) that enables the self-weight of the base 35 to be canceled. In this arrangement, in the position control step (S1), for an electric line of each motor mechanism 45, the stage controller 70 according to the present embodiment performs model following control as shown in FIG. 7. FIG. 7 is a block diagram showing a control algorithm of each motor mechanism 45.

In the model following control, each drive motor 46 is controlled so as to eliminate the delay time in the torque due to the pneumatic pressure in the cylinder mechanism 50. The stage controller 70 determines a drive state of each motor mechanism 45 by using both the target position of a corresponding drive unit 41 and the self-weight of the base 35, as inputs in the model following control. The “target position” of each drive unit 41 is a position profile indicating a trajectory of the wafer W obtained when raising the wafer W. The target position of each drive unit 41 is calculated based on (i) a position obtained upon completion of the translation movement of the stage 30, (ii) a scheduled contact position of each probe 22 of the probe card 21 with the wafer W, and (iii) a position or the like at which conduction between each probe 22 and the wafer W is completed. Further, the stage controller 70 may detect the inclination of the wafer W with respect to each probe 22, based on image information or the like from the stage-side camera 19 and the test-side camera 29, and then the stage controller 70 may calculate one or more target positions that are used to correct the inclination of the wafer W.

The stage controller 70 has an interior main controller 78 that performs the model following control. The interior of the main controller 78 has a trajectory generation unit 781, a mechanism plant unit 782, a first calculation unit 783, a second calculation unit 784, a third calculation unit 785, an electro-pneumatic compensation unit 786, a first adder 787, and a second adder 788.

In response to receiving the target position, the trajectory generation unit 781 is configured to calculate trajectories of the wafer W and the base 35 during the raising of the wafer and the base. In other words, the trajectory generation unit 781 calculates a position, velocity, and acceleration (current) of each drive motor 46 for each unit time. For example, the trajectory generation unit 781 preliminarily stores an appropriate function capable of generating the trajectory, and calculates the trajectory based on a given target position. As an example of this function, the following equation is used.

Km/s²+2ξωₙₛ+ωₙ²

Here, Kₘ is an amount of trajectory movement, ξ is a parameter of an overshoot amount, and ωₙ is a parameter of response speed.

The trajectory generation unit 781 calculates the trajectory (position, velocity, and acceleration) of each drive motor 46, then outputs trajectory values to the third calculation unit 785, and outputs the trajectory values to the first adder 787.

The mechanism plant unit 782 outputs the power supply amount calculated by the model following control to each motor mechanism 45, and feeds back the actual position, actual velocity, and actual acceleration of each drive motor 46 that are detected by a corresponding motor mechanism 45. For example, the mechanism plant unit 782 outputs the actual position, actual velocity, and actual acceleration of each motor mechanism 45 to the first calculation unit 783, and outputs the actual position of each drive motor 46 to the first adder 787.

The first calculation unit 783 integrates both (i) actual state variables (actual position, actual velocity, and actual acceleration) of each drive motor 46 that are received from the mechanism plant unit 782 and (ii) coefficient k1 defined in a design of the model following control, to thereby calculate state variables for correction of each drive motor 46.

The first adder 787 calculates a difference between the position of each drive motor 46 received from the trajectory generation unit 781, and the actual position of a corresponding drive motor 46 received from the mechanism plant unit 782, and outputs the difference to the second calculation unit 784.

The second calculation unit 784 is an integrator that integrates coefficient k2 defined in the design of the model following control and that integrates a difference calculated by the first adder 787. In this arrangement, the second calculation unit 784 can obtain a position steady-state error (error) of each motor mechanism 45. The position steady-state error is sent to the second adder 788, and is used as a state variable for correction.

The third calculation unit 785 integrates both (i) the trajectory (position, velocity, and acceleration) of each drive motor 46 received from the trajectory generation unit 781 and (ii) coefficient k3 defined in the design of the model following control, to thereby calculate state variables for trajectory tracking of each drive motor 46.

In response to receiving the self-weight of the base 35, the electro-pneumatic compensation unit 786 determines the pneumatic pressure from the electro-pneumatic regulator 542, and then calculates acceleration (or a current value) to be applied to the Z-axis movable body 42 through each cylinder mechanism 50, based on the determined pneumatic pressure. When determining the pneumatic pressure, the electro-pneumatic compensation unit 786 calculates a delay time of increase in the pneumatic pressure with respect to elapsed time, and as a result, the acceleration to be applied to the Z-axis movable body 42 also shows a variation accounting for the delay time.

The second adder 788 determines a control variable of each drive motor 46 based on the state variables (position, velocity, and acceleration) received from the first calculation unit 783, the second calculation unit 784, the third calculation unit 785, and the electro-pneumatic compensation unit 786. In the position control step (S1), the control variable determined by the second adder 788 is applied to the power supply of each motor mechanism 45 via the mechanism plant unit 782.

In the model following control, the coefficients k1, k2, and k3 for the first calculation unit 783, the second calculation unit 784, and the third calculation unit 785 are calculated by adopting the following design approach. That is, when state equations given in the mechanism plant unit 782 can be expressed by Equation (1) below.

$$\begin{matrix}[ Math . 1 ] & \\ \dot{x} ( t ) = A x ( t ) + B u ( t ) & ( 1 )\end{matrix}$$

$$y ( t ) = {C}^{T} x ( t )$$

In this case, a reference model can be expressed by Equation (2) below.

$$\begin{matrix}[ Math . 2 ] & \\ {x}_{m} ( t ) = A {x}_{m} ( t ) + {B}_{m} u ( t ) & ( 2 )\end{matrix}$$

$${y}_{m} ( t ) = {C}_{m}^{T} ( t ) {x}_{m}$$

Here, when an error is expressed by e(t)=y(t)−yₘ(t), and uₘ is used as a step input, an expanded system can be defined by Equation (3).

$$\begin{matrix}[ Math . 3 ] & \\ {\dot{x}}_{a} ( t ) = {A}_{a} {x}_{a} ( t ) + {B}_{a} {\dot{u}}_{t} ( t ) & ( 3 )\end{matrix}$$

$${x}_{a} = {[ \dot{{x}^{T}} {e}^{T} ( t ) \dot{{x}_{m}^{T}} ]}^{T} {A}_{a} = [ \begin{matrix}A & 0 & 0 \\ {C}^{T} & 0 & - {C}_{m}^{T} \\ 0 & 0 & A\end{matrix} ] {B}_{a} = [ \begin{matrix}B \\ 0 \\ 0\end{matrix} ]$$

For Equation (3), a quadratic evaluation function is adopted as expressed by Equation (4).

$$\begin{matrix}[ Math . 4 ] & \\ J = {\int }_{0}^{∞} \{ {e}^{T} ( t ) {Q}_{e} ( t ) e ( t ) + \dot{{u}^{T} ( t )} R \dot{u} ( t ) \} dt & ( 4 )\end{matrix}$$

An optimal control input u(t) that minimizes a value of Equation (4) is expressed by Equation (5), and is a solution of the Riccati equation as expressed by Equation (6).

$$\begin{matrix}[ Math . 5 ] & \\ u ( t ) = {k}_{1} x ( t ) + {k}_{2} {\int }_{0}^{t} e ( τ ) d τ + {k}_{3} {x}_{m} ( t ) & ( 5 )\end{matrix}$$

$$[ {k}_{1} {k}_{2} ] = - {R}^{- 1} [ {B}^{T} 0 ] {P}_{11} {k}_{3} = - {R}^{- 1} [ {B}^{T} 0 ] {P}_{12} {P}_{11} , {P}_{12}$$

$$\begin{matrix}[ Math . 6 ] & \\ {A}_{1}^{T} {P}_{11} + {P}_{11} + {Q}_{1} - {P}_{11} {B}_{1} {R}^{- 1} {B}_{1}^{T} {P}_{11} = 0 {A}_{1}^{T} {P}_{11} + {P}_{11} {A}_{2} + {P}_{12} {A}_{m} - {P}_{11} {B}_{1} {R}^{- 1} {B}_{1}^{T} {P}_{12} = 0 & ( 6 )\end{matrix}$$

$${A}_{1} = [ \begin{matrix}A & 0 \\ {C}^{T} & 0\end{matrix} ] {B}_{1} = [ \begin{matrix}B \\ 0\end{matrix} ] {A}_{2} = [ \begin{matrix}0 \\ - {C}_{m}^{T}\end{matrix} ] {Q}_{1} = [ \begin{matrix}0 & 0 \\ 0 & Q\end{matrix} ]$$

The stage controller 70 appropriately adjusts weighting coefficients of Equation (6) to calculate coefficients k1, k2, and k3 that minimize J in Equation (4). The weighting coefficients follow, for example, a pattern of weighting an error term and a pattern of weighting a differential amount of increase. Then, the stage controller 70 applies the calculated coefficients k1, k2, and k3, to thereby perform the model following control based on functional blocks shown in FIG. 7. In this arrangement, the stage controller 70 can rotate and drive each motor mechanism 45, so as to compensate for the delay time from the start of the position control step (S1) until the torque of the cylinder mechanism 50 reaches the target torque. That is, in the position control step (S1), each motor mechanism 45 can appropriately raise the Z-axis movable body 42 along the trajectory while accounting for the torque due to the delayed pneumatic pressure in the cylinder mechanism 50.

The test apparatus 1 and the stage 30 according to the present embodiment are basically configured as described above, and a method for operating the stage 30 will be described below.

While the wafer W is tested, the controller 90 of the test apparatus 1 transmits a movement command for the stage 30 to the stage controller 70, and the stage controller 70 controls the stage 30 based on the movement command. As described above, the stage controller 70 moves the wafer W in the horizontal direction through the X-axis movement mechanism 33 and the Y-axis movement mechanism 34 of the movement unit 32, and as a result, the wafer W faces the probe card 21.

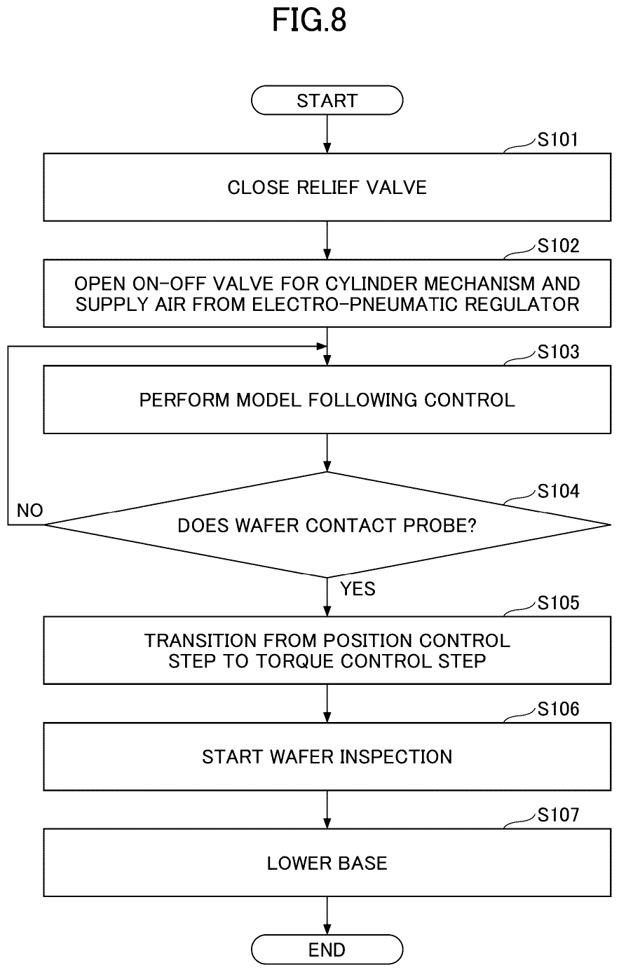

Next, the stage controller 70 moves the wafer W in the vertical direction through the Z-axis movement mechanism 40. In this case, the stage controller 70 sequentially performs both the position control step (S1) and the torque control step (S2) (see FIG. 4A). More specifically, the stage controller 70 performs control in which the base 35 of the stage 30 is raised according to a process flow shown in FIG. 8.

At the start of the position control step (S1), the stage controller 70 first closes the relief valve 544 for the cylinder mechanism 50 (step S101). With this approach, a space from the closed open-close valve 543 to each recess 52 of the disk-shaped housing 51 is sealed.

Next, the stage controller 70 opens the open-close valve 543 of the cylinder mechanism 50, and supplies air from the electro-pneumatic regulator 542 (step S102). In this case, the stage controller 70 transmits, to the electro-pneumatic regulator 542, a command to set pneumatic pressure (torque) corresponding to the self-weight of the base 35. As a result, the supply/discharge mechanism 54 supplies air to each recess 52 via the supply/discharge path 541, and raises each Z-axis movable body 42 in accordance with increasing pneumatic pressure. However, the pneumatic pressure in each recess 52 gradually increases with elapsed time.

In such a case, while supplying the air to the cylinder mechanisms 50, the stage controller 70 simultaneously performs the model following control for the drive motors 46 of the motor mechanisms 45, based on the delay time of the pneumatic pressure (step 103). By the above model following control, even in a transient phase where the pneumatic pressure does not reach the target torque, each drive unit 41 can align a vertical position of the wafer W along the generated trajectory, by driving a corresponding motor mechanism 45.

When performing the model following control, the stage controller 70 acquires an actual position of the wafer W, and determines the contact between each DUT and a corresponding probe 22 based on the actual position of the wafer W (step S104). If the stage controller 70 determines the contact between one or more probes 22 and the wafer W (YES in step S104), the stage controller 70 terminates the position control step (S1), and then proceeds to the torque control step (S2). On the other hand, if each probe 22 is not in contact with the wafer W, the stage controller 70 returns to step S103, and continues the model following control. For example, as shown in FIG. 4B, the switching from the position control step (S1) to the torque control step (S2) is performed after the target torque (target pneumatic pressure) of the cylinder mechanism 50 is reached. If each probe 22 is not in contact with the wafer W even after the target torque (target pneumatic pressure) of the cylinder mechanism 50 is reached, the position control shown in FIG. 5 is continuously performed.

When the stage controller 70 switches to the torque control step (S2), the stage controller 70 performs torque control according to the load applied to each motor mechanism 45, regardless of the position and/or velocity (step 105). In this case, each cylinder mechanism 50 cancels the self-weight of the base 35 by maintaining the supplying of pneumatic pressure through the electro-pneumatic regulator 542. With this arrangement, each drive unit 41 can support the base 35 properly, and start an overdrive operation of the wafer W with respect to each probe 22. That is, by raising the base 35 according to the load (torque) that is applied to the wafer W from each probe 22, each motor mechanism 45 can easily adjust the wafer W and the base 35 to positions where a given probe 22 contacts the DUT.

After performing the overdrive operation, electrical testing for the wafer W is started (step S106). During the test, each drive unit 41 continues to apply the target torque (target pneumatic pressure) corresponding to the self-weight of the base 35 to a corresponding Z-axis movable body 42, by the cylinder mechanism 50, and also, each drive unit 41 continues to apply torque corresponding to a load applied from each probe 22, by the motor mechanism 45. In comparison with a conventional mechanism that raises a base by only motor mechanisms, the test apparatus 1 can maintain the vertical position of the base 35 properly while greatly reducing power consumption. By closing the open-close valve 543 and the relief valve 544, the test apparatus 1 may be configured to maintain the target torque (target pneumatic pressure) in each recess 52. In the test apparatus 1, a normally closed valve may be used as each of the open-close valve 543 and the relief valve 544. In this arrangement, it is possible to appropriately maintain the target torque (target pneumatic pressure) in each recess 52, to thereby prevent the base 35 from dropping rapidly during a power outage or the like of the test apparatus 1.

After the test of the wafer W, the stage controller 70 lowers the base 35 to separate the wafer W from the probes 22 (step 107). In this case, the stage controller 70 first stops the power supply to each motor mechanism 45, and slightly lowers the base 35. Then, the stage controller 70 closes the open-close valve 543 for the cylinder mechanism 50, and stops the supply of the pneumatic pressure from the electro-pneumatic regulator 542. Then, the stage controller 70 gradually reduces the pneumatic pressure in each recess 52 by releasing the relief valve 544 into the atmosphere, and thus lowers each Z-axis movable body 42.

After lowering the wafer W and the base 35, the stage controller 70 moves the stage 30 in the horizontal direction, and takes out the tested wafer W from the loader 13. This completes the test of the wafer W.

The test apparatus 1, the stage 30, and the method for operating the test apparatus 1 according made. For example, in the above-described embodiments, a configuration is adopted in which air is supplied and discharged as a pressure medium in the cylinder mechanism 50. However, the configuration of the cylinder mechanism 50 is not limited to the above example, and may be adopted such that liquid (for example, oil) is applied as the pressure medium, that is, the base 35 is raised and lowered based on the supply and discharge of hydraulic (oil) pressure.

For example, as a control method during the raising of the base 35, during the position control step (S1), the stage controller 70 may temporarily stop the supply of the pneumatic pressure by the cylinder mechanisms 50, and may perform the position control by the motor mechanisms 45. As an example, the stage controller 70 closes the relief valve 544 to atmosphere while closing the open-close valve 543.

Further, in the torque control step (S2), after one or more probes 22 contact the wafer W, the stage controller 70 closes the relief valve 544 and opens the open-close valve 543, to thereby supply pneumatic pressure to the recesses 52. In this case, for each motor mechanism 45, the stage controller 70 maintains the power of the position control step (S1).

Then, the stage controller 70 adjusts the pneumatic pressure of the cylinder mechanism 50, so as to correspond to the load applied from each probe 22 to the wafer W. Thus, the pneumatic pressure corresponding to the load applied from each probe 22 is applied to the base 35, and the stage 30 can also reduce the power consumption of the the motor mechanisms 45. When adjusting the pneumatic pressure that corresponds to the load applied from each probe 22 to the wafer W, the Z-axis movement mechanism 40 may include a pressure sensor 59 (see the dotted line in FIG. 3) that detects the pneumatic pressure, and may adjust an elevation position of the base 35 based on actual pressure detected by the pressure sensor 59. In this arrangement, the stage 30 can more accurately adjust elevation positions of the wafer W and the base 35.

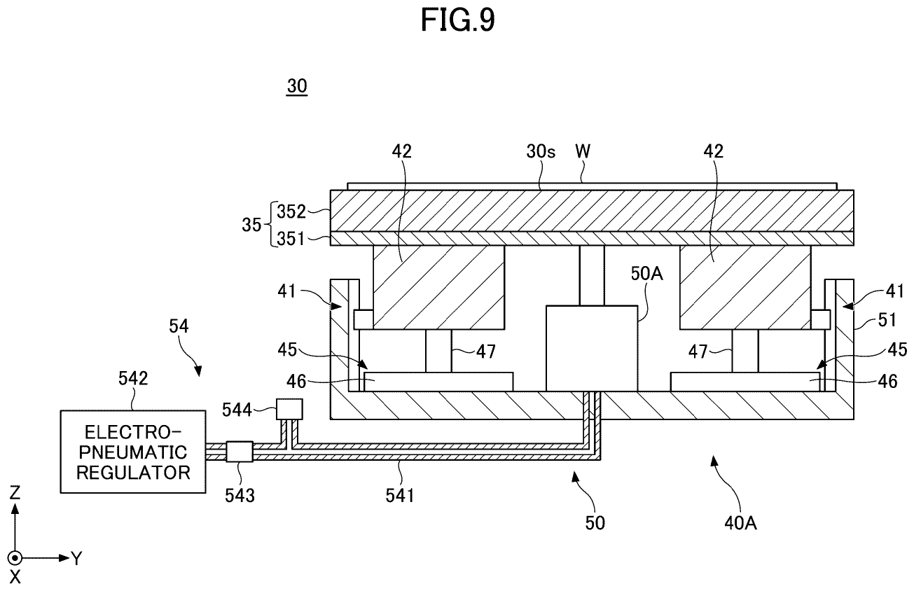

FIG. 9 is a side view showing a Z-axis movement mechanism 40A in a modification. As shown in FIG. 9, the Z-axis movement mechanism 40A in the present disclosure may include motor mechanisms 45 and a cylinder mechanism 50 at different positions. For example, the cylinder mechanism 50 supports the center of the base 35 by a main body 50A, and raises and lowers the base 35 based on the pneumatic pressure in the main body 50A. Alternatively, the Z-axis movement mechanism 40A may include main bodies 50A, and may support the base 35, and raise and lower the base 35, through the main bodies 50A. When adjusting the tilt of the base 35, it is desirable that the pneumatic pressure be uniform across the lower surface of the bottom plate 351. In FIG. 3, by supplying the pneumatic pressure to the recess 52 of each cylinder mechanism 50, the cylinder mechanism 50 simultaneously compensates for the self-weight that is applied to the bottom plate 351, with the pneumatic pressure such that the weight is uniformly distributed, while the motor mechanism 45 adjusts the tilt of the Z-axis movable body 42. On the other hand, in FIG. 9, since the supply of air to the lower surface of the Z-axis movable body 42 is not limiting unlike a case where the air is supplied to the recesses 52, more uniform pneumatic pressure can be applied by directly supplying the pneumatic pressure to the lower surface of the bottom plate 351. In this case, it is preferable to configure a supply area such that pneumatic pressure can be supplied to the entire surface of the bottom plate 351.

The technical concept and effects of the present disclosure described in the above embodiments will be described below.

A first aspect of the present disclosure is a stage 30 on which a substrate (wafer W) is mounted and that raises and lowers the substrate. The stage 30 includes a base 35 on which the substrate is to be mounted, and includes an elevation mechanism (Z-axis movement mechanism 40 or 40A) configured to raise and lower the base 35. The elevation mechanism includes a first adjustment unit (motor mechanism 45) configured to adjust an elevating position of the base 35 by rotational drive of a drive motor 46. The elevation mechanism includes a second adjustment unit (cylinder mechanism 50) configured to supply and discharge a pressure medium, and adjust the elevating position of the base 35 through the pressure medium.

In this aspect, the stage 30 has the first adjustment unit (motor mechanism 45) and the second adjustment unit (cylinder mechanism 50), and as a result, a substrate can be easily raised and lowered with high accuracy while reducing the cost of raising and lowering the substrate. That is, since the stage 30 raises and lowers the base 35 based on the pressure of a pressure medium in the second adjustment unit, consumption of power supplied to the drive motor 46 of the first adjustment unit can be suppressed. Moreover, the stage 30 can finely adjust the elevation position of the substrate by the drive motor 46, and can stably place the substrate at a target position.

A stage 30 may include a controller (stage controller 70) configured to adjust an elevation position of a base, while interlocking a first adjustment unit (motor mechanism 45) and a second adjustment unit (cylinder mechanism 50) with each other. By controlling the first adjustment unit and the second adjustment unit in such an interlocking manner, the stage 30 can move the base 35 to the elevation position with increased accuracy.

A first adjustment unit (motor mechanism 45) may include a torque detector (torque sensor 49) configured to detect torque of a drive motor 46, and a controller (stage controller 70) may adjust an elevation position of a base 35 based on the torque detected by the torque detector. In this arrangement, the stage 30 can perform torque control when raising and lowering the base 35 based on the torque that is actually applied to a substrate (wafer W) and the base 35.

An elevation mechanism (Z-axis movement mechanism 40) may include a position detector (encoder 48) that detects a position and/or velocity of a base 35, and a controller (stage controller 70) may perform a position control step and a torque control step in this order. The position control step adjusts an elevation position of the base 35 based on (i) the position and/or velocity detected by the position detector and (ii) the torque detected by a torque detector (torque sensor 49). The torque control step adjusts the elevation position of the base 35 based on the torque detected by the torque detector. In this arrangement, while accurately adjusting a position of the base 35 in a position control step, a stage 30 can apply desired torque to the base 35 in a torque control step.

In a position control step, a controller (stage controller 70) may supply a pressure medium by a second adjustment unit (cylinder mechanism 50), and may control rotation drive of a drive motor 46 by a first adjustment unit (motor mechanism 45) based on delay time in supply of the pressure medium. In this arrangement, even when the delay time occurs when supplying the pressure medium, the stage 30 can rotate and drive a drive motor 46 so as to eliminate the delay time. As a result, a stage 30 can appropriately adjust the elevation position of a substrate (wafer W) along a target.

A controller (stage controller 70) may shift from a position control step to a torque control step after torque obtained based on pressure of a pressure medium by a second adjustment unit (cylinder mechanism 50) reaches target torque. In this arrangement, the controller can smoothly shift from the position control step to the torque control step, and can prevent the occurrence of insufficient torque that supports a base 35.

A controller (stage controller 70) may adjust pressure of a pressure medium by a second adjustment unit (cylinder mechanism 50), so as to offset the self-weight of a base 35. In this arrangement, a stage 30 can adjust an elevation position of a substrate (wafer W) while ignoring the self-weight of the base 35 when driving a first adjustment unit (motor mechanism 45).

An elevation mechanism (Z-axis movement mechanism 40) may include three or more first adjustment units (motor mechanisms 45), and a controller (stage controller 70) may independently control the three or more first adjustment units to correct the tilt of a base 35. In this arrangement, a stage 30 can stably eliminate the tilt of a substrate (wafer W) and a base 35.

A second adjustment unit (cylinder mechanism 50) may include a pressure detector (pressure sensor 59) that detects the pressure of a pressure medium, and a controller (stage controller 70) may adjust an elevation position of a base 35 based on the pressure detected by the pressure detector. In this arrangement, a stage 30 can be properly adjust to a target position even when an elevation position is adjusted by a second adjustment unit.

A drive motor 46 may be a direct drive motor. In this arrangement, a stage 30 can be made compact as much as possible, and direct torque control can be easily implemented without a reduction gear.

A second adjustment unit (cylinder mechanism 50) may include a housing (disk-shaped housing 51) and a movable body (Z-axis movable body 42) that is slidably housed in a recess 52 provided in the housing. A first adjustment unit (motor mechanism 45) may include a drive motor 46 provided in the recess 52, and the first adjustment unit may raise and lower a movable body via a power conversion unit 47 that converts rotational drive of the drive motor 46 into linear drive. In this arrangement, a stage 30 can be further made compact, and the movable body can be stably raised and lowered.

A second adjustment unit (cylinder mechanism 50) may include a supply/discharge path 541 that supplies and discharges pneumatic pressure, which is a pressure medium, to and from a recess 52; an electro-pneumatic regulator 542 that is provided in the supply/discharge path 541 and is capable of adjusting the pneumatic pressure; an open-close valve 543 that is provided in the supply/discharge path 541 between an electro-pneumatic regulator 542 and a recess 52 and that is capable of opening and closing a flow path of the supply/discharge path 541; and a relief valve 544 provided in the supply/discharge path 541 between the electro-pneumatic regulator 542 and the recess 52, the relief valve 544 being capable of switching between opening atmosphere and closing of the supply/discharge path 541. In this arrangement, a stage 30 can easily and accurately adjust the pressure of a second adjustment unit.

A second aspect of the present disclosure is a test apparatus 1. The test apparatus includes (i) a stage 30 on which a substrate (wafer W) is mounted and that raises and lowers the substrate; (ii) probes 22 that come into contact with the substrate as the substrate is raised; and (iii) a tester 20 that tests the substrate by transmitting and receiving signals to and from the substrate through the probes 22. A stage 30 includes a base 35 on which the substrate is mounted, and an elevation mechanism (Z-axis movement mechanism 40) that raises and lowers the base 35. The elevation mechanism includes a first adjustment unit (motor mechanism 45) that adjusts an elevation position of the base 35 by rotational drive of a drive motor 46. The elevation mechanism includes a second adjustment unit (cylinder mechanism 50) that adjusts the elevation position of the base 35 by the supplying and discharging of a pressure medium.

A third aspect of the present disclosure is a method for operating a stage 30 on which a substrate (wafer W) is mounted and that raises and lowers the substrate. The method includes: adjusting an elevation position of a base 35 by rotational drive of a drive motor 46 that is provided in a first adjustment unit (motor mechanism 45), when raising and lowering the base 35 on which the substrate is mounted; adjusting the elevation position of the base 35 by supplying and discharging of a pressure medium in a second adjustment unit (cylinder mechanism 50). In the second and third aspects, the substrate can be easily and accurately raised and lowered while reducing the cost of raising and lowering the substrate.

A stage 30, a test apparatus 1, and a method for operating the stage 30 according to the present embodiment are examples in all respects and are not limiting. From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended

The stage 30 of the present disclosure is not limited to the application to the test apparatus 1, and may be applied, for example, to a configuration that supports a substrate, and raises and lowers the substrate in a substrate processing apparatus that processes the substrate (wafer W).

In the present disclosure, a substrate can be easily raised and lowered with high accuracy while reducing the cost of raising and lowering the substrate.

What is claimed is:

1. A stage comprising:
a base on which a substrate is to be mounted; and
an elevation mechanism configured to raise and lower the base, the elevation mechanism including:
at least one first adjustment mechanism configured to adjust an elevation position of the base by rotational drive of a drive motor, and
a second adjustment mechanism configured to supply and discharge a pressure medium, and adjust the elevation position of the base through the pressure medium.

2. The stage according to claim 1, further comprising:
a controller configured to adjust the elevation position of the base, while interlocking the first adjustment mechanism and the second adjustment mechanism with each other.

3. The stage according to claim 2, wherein the first adjustment mechanism includes a torque detector configured to detect torque of the drive motor, and
wherein the controller is configured to adjust the elevation position of the base based on the torque detected by the torque detector.

4. The stage according to claim 3, wherein the elevation mechanism includes a position detector configured to detect at least one of a position or velocity of the base, and
wherein the controller is configured to:
perform position control to adjust the elevation position of the base based on both (i) the at least one of the position or the velocity detected by the position detector and (ii) the torque detected by the torque detector, and
perform torque control to adjust the elevation position of the base based on the torque detected by the torque detector.

5. The stage according to claim 4, wherein in the position control, the controller is configured to
supply the pressure medium by the second adjustment mechanism, and
control the rotational drive of the drive motor by the first adjustment mechanism, based on delay time in the supply of the pressure medium.

6. The stage according to claim 5, wherein the controller is configured to shift from the position control to the torque control after the torque that is based on pressure of the pressure medium by the second adjustment mechanism reaches target torque.

7. The stage according to claim 2, wherein the controller is configured to adjust pressure of the pressure medium by the second adjustment mechanism such that self-weight of the base is compensated.

8. The stage according to claim 2, wherein the at least one first adjustment mechanism includes three or more first adjustment mechanisms, and
wherein the controller is configured to independently control the three or more first adjustment mechanisms to correct a tilt of the base.

9. The stage according to claim 2, wherein the second adjustment mechanism includes a pressure detector configured to detect pressure of the pressure medium, and
wherein the controller is configured to adjust the elevation position of the base based on the pressure detected by the pressure detector.

10. The stage according to claim 1, wherein the drive motor is a direct drive motor.

11. The stage according to claim 1, wherein the second adjustment mechanism includes a housing and a movable body that is slidably housed in a recess in the housing, and
wherein the first adjustment mechanism includes the drive motor in the recess, the first adjustment mechanism being configured to raise and lower the movable body via a power converter that converts the rotational drive of the drive motor into linear drive.

12. The stage according to claim 11, wherein the second adjustment mechanism includes:
a supply/discharge path configured to supply and discharge pneumatic pressure to the recess as the pressure medium,
an electro-pneumatic regulator provided in the supply/discharge path, and configured to adjust the pneumatic pressure,
an open-close valve provided in the supply/discharge path that is between the electro-pneumatic regulator and the recess, the open-close valve being configured to open and close a flow path of the supply/discharge path, and
a relief valve provided in the supply/discharge path that is between the electro-pneumatic regulator and the recess, the relief valve being configured to switch between atmospheric release and isolation of the supply/discharge path.

13. A test apparatus comprising:
a stage including:
a base on which a substrate is to be mounted, and
an elevation mechanism configured to raise and lower the substrate, the elevation mechanism including
a first adjustment mechanism configured to adjust an elevation position of the base by rotational drive of a drive motor,
at least one second adjustment mechanism configured to supply and discharge a pressure medium, and adjust the elevation position of the base through the pressure medium;
probes configured to contact the substrate as the substrate rises; and
a tester configured to transmit and receive signals to and from the substrate via the respective probes, and test the substrate based on the signals.

14. A method for operating a stage, comprising:
raising and lowering a base of the stage on which a substrate is mounted;
adjusting an elevation position of the base by rotational drive of a drive motor;
supplying and discharging a pressure medium; and
adjusting the elevation position of the base through the pressure medium.
